(19) United States
(12) Patent Application Publication
(10) Pub. No.: US 2008/0283502 A1
(43) Pub. Date: Nov. 20, 2008

(54) Compositions, methods and systems for polishing aluminum oxide and aluminum oxynitride substrates

(76) Inventors: Kevin Moeggenborg, Naperville, IL (US); Mukesh Desai, Naperville, IL (US)

Correspondence Address: STEVEN WESEMAN;ASSOCIATE GENERAL COUNSEL, I.P., CABOT MICROELECTRONICS CORPORATION, 870 NORTH COMMONS DRIVE, AURORA, IL, 60504, US

(21) Appl. No.: 11/442,475

(22) Filed: May 26, 2006

(51) Int. Cl. C09K 13/00; C03C 15/00; H01L 21/302

(52) U.S. Cl. 216/88; 252/79.1; 438/689

(57) ABSTRACT

A method and system is provided for improved polishing or planarizing of aluminum oxide and/or aluminum oxynitride substrates. Specifically, the composition comprises an abrasive, a liquid carrier, and a phosphorus-type mono-acid. Preferably, the phosphorus-type mono-acid is phosphoric acid, phosphonoacetic acid, phosphorous acid, methyl phosphonic acid, or mixtures thereof. The control of the pH of the composition further improves polishing rates.

### TECHNICAL FIELD

The present invention relates to compositions and methods for polishing substrates. More particularly, the present invention further relates to methods and systems for chemical-mechanical polishing of aluminum oxide or aluminum oxynitride surfaces.

### BACKGROUND

Aluminum oxide (Al₂O₃) substrates, such as sapphire substrates, and aluminum oxynitride substrates, are generally useful in many applications, such as commercial, industrial, scientific and military applications. These substrates are generally very strong and transparent materials, making them useful for window, substrate and dome applications. In addition, aluminum oxide and aluminum oxynitride tolerate very high temperatures, making them particularly useful in electronic applications where high heat is generated.

One electronic application for aluminum oxide and/or aluminum oxynitride is use as a crystal in laser applications. Specifically, sapphire crystals having titanium or chromium dopants are useful in laser applications, especially in the red to near-infrared region of the electromagnetic spectrum.

Pure crystals of aluminum oxide can be grown into large single-crystal ingots, which can be sliced into wafers and polished to form hard, strong, temperature-resistant and transparent crystal slices. For example, such slices may be used as watch faces in high quality watches, as the material's exceptional hardness makes the face almost impossible to scratch. Wafers of single crystal aluminum oxide are also used in the semiconductor industry as a substrate for the growth of gallium nitride based blue and green light emitting diodes.

To take advantage of the use of aluminum oxide and aluminum oxynitride substrates in many different applications, including in microelectronics, substrates made from aluminum oxide and/or aluminum oxynitride must be polished or planarized to provide a smooth, clean surface. Typically, polishing or planarizing of aluminum oxide and/or aluminum oxynitride substrates involves use of a liquid composition having an abrasive material therein to abrade the surface of the substrate with the use of a polishing pad, commonly known as a chemical-mechanical polishing (“CMP”) process.

In a typical CMP process, the substrate is placed in direct contact with a rotating polishing pad. A carrier applies pressure against the backside of the substrate. During the polishing process, the pad and table are rotated while a downward force is maintained against the substrate back. An abrasive and chemically reactive solution, commonly referred to as a “slurry,” is deposited onto the pad during polishing. The slurry initiates the polishing process by chemically reacting with the substrate being polished. The polishing process is facilitated by the rotational movement of the pad relative to the substrate as the slurry is provided to the substrate/pad interface. Polishing is continued in this manner until the desired polishing effect is accomplished.

Due to low material removal rates, polishing of aluminum oxide and/or aluminum oxynitride substrate surfaces suffers from long polishing times and low throughput. To improve polishing times, high concentrations of abrasives may be used. For example, slurries utilized to polish sapphire substrate surfaces have been known to comprise up to about 50% by weight abrasive concentration. High abrasive levels, however, can cause damaging levels of heat from frictional forces, which negatively impact the polishing pads utilized to polish the aluminum oxide and/or aluminum oxynitride substrates.

Therefore, a need exists for an improved composition for polishing aluminum oxide and/or aluminum oxynitride substrates. Specifically, a need exists for a composition that increases removal rates. Moreover, a need exists for improved systems and methods for polishing aluminum oxide and/or aluminum oxynitride substrates utilizing an improved composition.

### SUMMARY

In an embodiment of the present invention, a method for polishing a substrate is provided. The method comprises the steps of: providing a composition comprising an abrasive, a liquid carrier, and a phosphorus-type mono-acid wherein said composition has a pH of between about 1 and about 7; providing a substrate selected from the group consisting of aluminum oxide and aluminum oxynitride; providing means for physically abrading the substrate; and abrading at least a portion of the substrate by contacting the substrate with the means for physically abrading the substrate and the composition.

In a still further embodiment of the present invention, a chemical mechanical polishing system is provided. The system comprises a composition comprising an abrasive, a liquid carrier, and a phosphorus-type mono-acid wherein said composition has a pH of between about 1 and about 7, a substrate selected from the group consisting of aluminum oxide and aluminum oxynitride, and means for physically abrading the substrate.

Additional features and advantages of the present invention are described in, and will be apparent from, the detailed description of the presently preferred embodiments and from the drawings.

### BRIEF DESCRIPTION OF THE DRAWINGS

FIG. 1 shows a graph illustrating the dosage response to polishing (measured as removal rate in nm/min) of a sapphire wafer with slurries containing varying amounts of phosphoric acid.

FIG. 2 shows a graph illustrating the removal rate of a sapphire wafer with a series of slurries containing varying amounts of phosphoric acid and varying pH.

FIG. 3 shows a graph illustrating the delta drag force (in Newtons) of polishing of a sapphire wafer with a series of slurries containing various amounts of phosphoric acid and varying pH.

### DETAILED DESCRIPTION OF THE PRESENTLY PREFERRED EMBODIMENTS

A composition is provided for improved polishing of aluminum oxide substrates, such as sapphire, and/or aluminum oxynitride substrates. Specifically, the composition comprises an abrasive, a liquid carrier, and a phosphorus-type mono-acid. The control of pH further improves polishing rates. Moreover, systems and methods of polishing aluminum oxide and/or aluminum oxynitride substrates are provided.

As noted, the substrate that is polished or planarized according to the present invention involves aluminum oxide, commonly known as alumina, and/or aluminum oxynitride. Specifically, a suitable substrate is sapphire. More specifically, the substrate is single crystal sapphire. Single crystal sapphire is a synthetic, transparent variety of aluminum oxide (Al₂O₃). Synthetic sapphire has been produced commercially since 1902. There are many crystal growth methods used to produce sapphire. A partial listing includes: the Czochralski method, Kyropoulos method, Vertical Gradient Freezing (“VGF”), and the Horizontal Directed Crystallization Method (J. Bohm, The History of Crystal Growth, American Association of Crystal Growth Newsletter Vol. 17 (2), pp. 2-4). Other methods of making sapphire crystals are contemplated by the present invention, and the present invention should not be limited to the partial listing noted above.

Sapphire wafers utilized as substrates in the present invention are preferably cut along the “C” plane, and are accordingly known as “C-plane sapphire.” However, the invention is not limited in this regard. Sapphire substrates useful as substrates may be cut in other ways, as well, including R-plane, M-plane, and A-plane.

The abrasive utilized in the present invention for polishing or planarizing the sapphire substrate can be any suitable metal oxide that can function as an abrasive. Suitable metal oxides include, without limitation, alumina, silica, titania, ceria, zirconia, germania, magnesia, and combinations thereof. Useful forms of silica include but are not limited to fumed silica, precipitated silica, and condensation-polymerized silica. Preferably, the silica is condensation-polymerized silica, and is sometimes referred to as colloidal silica. Condensation-polymerized silica particles typically are prepared by condensing Si(OH)₄ to form colloidal particles. Such abrasive particles can be prepared in accordance with U.S. Pat. No. 5,230,833, which is incorporated herein by reference in its entirety. Abrasive particles may further be obtained as any of various commercially available products, such as the Fuso PL-1 and PL-2 products, Akzo-Nobel Bindzil 50/80 product, and the Nalco 1050, 2327, and 2329 products, as well as other similar products available from DuPont, Bayer, Applied Research, Nissan Chemical, and Clariant, among others.

The method of the present invention includes a composition incorporating the abrasive into a liquid carrier. The abrasive is preferably suspended in the composition, more specifically in the liquid carrier component of the composition. When the abrasive is suspended in the composition, the abrasive is preferably colloidally stable. The term “colloidally stable” refers to the abrasive particles being maintained in suspension over time.

Typically, the abrasive has a mean particle size of between about 10 nm and about 500 nm. A preferred mean particle size for the abrasive is between about 20 nm and about 200 nm. Moreover, the abrasive may be incorporated into the liquid carrier at a concentration of between about 1 percent by weight and about 50 percent by weight. Preferably, the abrasive is present in a concentration of between about 5 percent by weight and about 30 percent by weight in the composition.

The phosphorus-type mono-acid of the present invention may be incorporated into the composition at a concentration of between about 0.0025 percent by weight and about 0.5 percent by weight. More preferably, the phosphorus-type mono-acid is incorporated into the composition at a concentration of between about 0.01 percent by weight and about 0.1 percent by weight. Preferably, the phosphorus-type mono-acid is phosphoric acid, phosphonoacetic acid, phosphorous acid, methylphosphonic acid, or mixtures thereof. However, any phosphorus-type mono-acid is useful for the present invention, and the invention should not be limited in this regard.

A liquid carrier is used to facilitate the application of the abrasive, the phosphorus-type mono-acid and any additives dissolved or suspended therein to the surface of a suitable substrate to be polished (e.g., planarized). The liquid carrier is typically an aqueous carrier and can be water alone (i.e., can consist of water), can consist essentially of water, can comprise water and a suitable water-miscible solvent, or can be an emulsion. Suitable water-miscible solvents include alcohols, such as methanol, ethanol, and ethers. Preferably, the aqueous carrier comprises, consists essentially of, or consists of water. More preferably, the aqueous carrier comprises, consists essentially of, or consists of deionized water.

The pH of the composition can be adjusted in any suitable manner, e.g., by adding a pH adjuster to the composition. Suitable pH adjusters include, for example, bases such as potassium hydroxide, ammonium hydroxide, sodium carbonate, and mixtures thereof, as well as acids, such as mineral acids (e.g., nitric acid, sulfuric acid and hydrochloric acid) and organic acids (e.g., acetic acid, citric acid, malonic acid, succinic acid, tartaric acid, and oxalic acid). Preferably, the pH of the composition is between about 1 and about 7. More preferably, the pH of the composition is between about 2 and about 4.5.

The composition optionally can further comprise one or more additives. Such additives include surfactants (e.g., cationic surfactants, anionic surfactants, nonionic surfactants, amphoteric surfactants, fluorinated surfactants, and mixtures thereof), polymeric stabilizers or other surface active dispersing agents, pH buffers, biocides, biostat, and chelating or complexing agents.

The method of the present invention includes physical abrasion of a substrate. Any means may be utilized to abrade the substrate, the substrate being in contact with the polishing composition. Without limitation, possible means for physically abrading a substrate can include a polishing pad, a polishing pad containing at least one fixed abrasive, a polishing belt, a polishing belt containing at least one fixed abrasive, brushes, polishers utilized in magnetorheological fluid polishing, elastic polishing tools and/or slurry jet polishing. A preferred embodiment for physically abrading a substrate is a polishing pad. Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, but are not limited to, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof.

The polishing pads can have any suitable dimension. Typically, the polishing pad will be circular in shape. The polishing pad comprises a polishing surface which optionally further comprises grooves, channels and/or perforations that facilitate the transport of polishing compositions across the surface of the polishing pad. Such grooves, channels, or perforations can be any suitable depth and width, as apparent to one having ordinary skill in the art. Preferably, the polishing pad comprises at least small grooves produced by standard pad conditioning methods.

The polishing pad can be used along or as one layer of a multi-layer stacked polishing pad. For example, the polishing pad can be used in combination with a subpad layer that is substantially coextensive with the polishing pad.

Surface roughness of polished aluminum oxide and/or aluminum oxynitride surfaces, such as wafers or other like aluminum oxide and/or aluminum oxynitride surfaces, can be measured with an atomic force microscope (AFM). Typically, a scan size of 2×2 μm is used and the average roughness (Rₐ) can be calculated for the scanned area. Generally, acceptable surface roughness values have an Rₐ of less than about 1.0 nm. Roughness values as low as about 0.1 nm to about 0.2 nm may be seen on highly polished surfaces.

### EXAMPLES

The following Examples further illustrate the invention but, of course, should not be construed as limiting the scope of the invention.

The following examples describe polishing formulations prepared and evaluated for polishing a 2 inch C-plane sapphire wafer. The polishing was performed on a Logitech CDP polishing tool, using a downforce pressure of 10.5 psi (approximately 0.738 kg/cm²), platen speed of 69 rpm, and a slurry feed rate of 160 ml/minute. The polishing pad used on the Logitech CDP polishing tool was a CMC D100 polishing pad, which is a polyurethane pad that was concentrically grooved to aid slurry flow. The polishing times were all 10 minutes. The polishing rates were calculated by measuring the weight loss of the polished wafer and converting to nm/min.

### Example 1

A 2.5 g aliquot of 40% phosphoric acid solution was added to 997 g of deionized water while stirring. To this solution, 1000 g of colloidal silica (40% solids with mean particle size of approximately 110 nm) was added while stirring. The pH was adjusted to 2.0 with a 10% HCl solution. The resulting solution contained a final phosphoric acid concentration of 0.05%.

### Example 2

A control slurry was prepared as described in Example 1, except that the phosphoric acid was omitted. The pH was adjusted to 2.3.

### Example 3

A 1.40 g aliquot of 100% phosphonoacetic acid solution was added to 998 g of deionized water while stirring. To this solution, 1000 g of colloidal silica (40% solids with mean particle size of approximately 110 nm) was added with stirring. The pH was adjusted to 2.17 with a 10% HCl solution. The resulting solution contained a final phosphonoacetic acid concentration of 0.07%.

### Example 4

A 0.80 g aliquot of 100% phosphorous acid solution was added to 999 g of deionized water while stirring. To this solution, 1000 g of colloidal silica (40% solids with mean particle size of approximately 110 nm) was added with stirring. The pH was adjusted to 2.17 with a 10% HCl solution. The resulting solution contained a final phosphorous acid concentration of 0.04%.

### Example 5

A 1.0 g aliquot of 100% methylphosphonic acid solution was added to 999 g of deionized water while stirring. To this solution, 1000 g of colloidal silica (40% solids with mean particle size of approximately 110 nm) was added with stirring. The pH was adjusted to 2.5 with a 10% HCl solution. The resulting solution contained a final methylphosphonic acid concentration of 0.05%.

### Example 6

A 0.9 g aliquot of 70% nitric acid solution was added to 999 g of deionized water while stirring. To this solution, 1000 g of colloidal silica (40% solids with mean particle size of approximately 110 mm) was added with stirring. The pH was adjusted to 2.5 with a 10% HCl solution. The resulting solution contained a final nitric acid concentration of 0.03%.

### Example 7

A 1.0 g aliquot of 96.5% sulfuric acid solution was added to 999 g of deionized water while stirring. To this solution, 1000 g of colloidal silica (40% solids with mean particle size of approximately 110 nm) was added with stirring. The pH was adjusted to 1.75 with a 10% HCl solution. The resulting solution contained a final sulfuric acid concentration of 0.05%.

### Example 8

A 1.0 aliquot of 100% sulfamic acid solution was added to 999 g of deionized water while stirring. To this solution 1000 g of colloidal silica (40% solids with mean particle size of approximately 110 nm) was added with stirring. The pH was adjusted to 2.21 with a 10% HCl solution. The resulting solution contained a final sulfamic acid concentration of 0.05%.

Table 1 illustrates the sapphire surface removal rate, in nm/min., of colloidal silica slurries, with phosphoric acid, phosphonoacetic acid, phosphorous acid, and methylphosphonic acid, at equimolar concentrations at a relatively low pH. Other common additives are listed as well to illustrate the enhanced removal rate of phosphorus-type mono-acid compounds. Examples 1-8 are listed in order of removal rate, with the compositions exhibiting higher removal rates listed first.

TABLE 1

| Example | | | Removal Rate |
|---|---|---|---|
| Number | Additive | pH | (nm/min) |
| 1 | Phosphoric acid | 2.5 | 76.4 |
| 3 | Phosphonoacetic acid | 2.17 | 45.1 |
| 4 | Phosphorous acid | 2.38 | 27.6 |
| 5 | Methylphosphonic acid | 2.54 | 25.1 |
| 6 | Nitric acid | 2.2 | 22.5 |
| 8 | Sulfamic acid | 2.21 | 20.0 |
| 2 | No additive | 2.32 | 17.5 |
| 7 | Sulfuric acid | 1.75 | 6.3 |

As shown in Table 1, phosphorus-type mono-acids, including phosphoric acid, phosphonoacetic acid, phosphorous acid, and methylphosphonic acid (Examples 1, 3, 4 and 5, respectively), show an enhanced sapphire removal rate, compared to adding no additive (Example 2). Moreover, phosphorus-type mono-acids also show enhanced removal rates compared to other simple mono-acids, such as nitric acid, sulfamic acid, and sulfuric acid.

### Examples 9-15

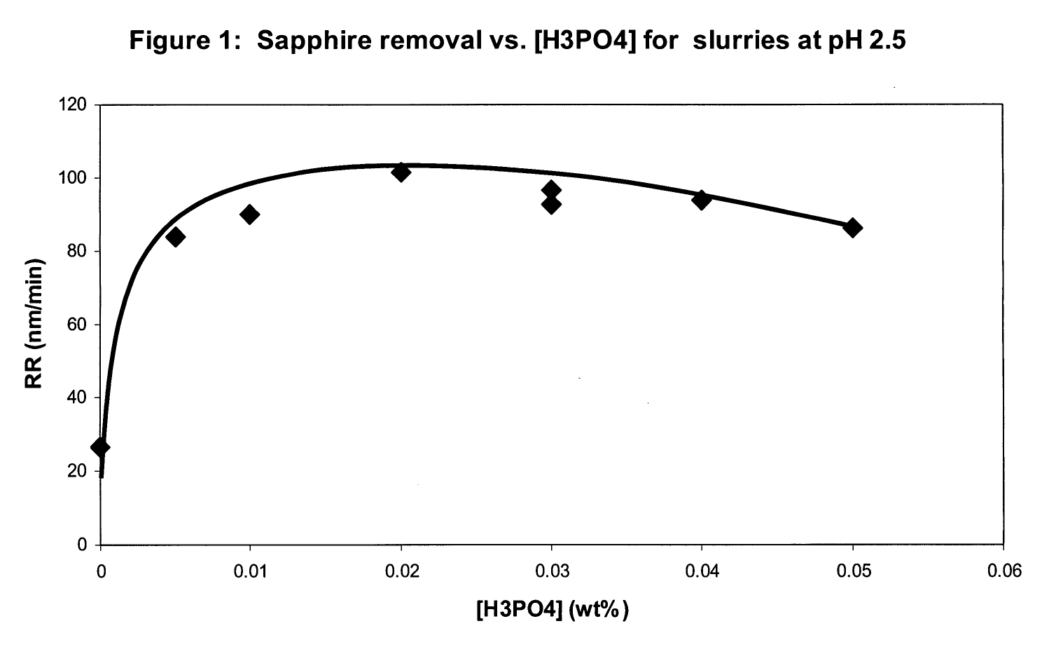

A series of slurries was prepared as described in Example 1, with varying levels of phosphoric acid. The final concentrations of phosphoric acid were 0% (Example 9), 0.005% (Example 10), 0.01% (Example 11), 0.02% (Example 12), 0.03% (Example 13), 0.04% (Example 14), and 0.05% (Example 15). The pH of all slurries of Examples 9-15 was adjusted to 2.5. The substrate, polishing tool and polishing conditions were as described for Examples 1-8 above. The results are illustrated in FIG. 1.

As can be seen in FIG. 1, the effect of phosphoric acid on sapphire removal rates can be seen at very low concentrations and low pH.

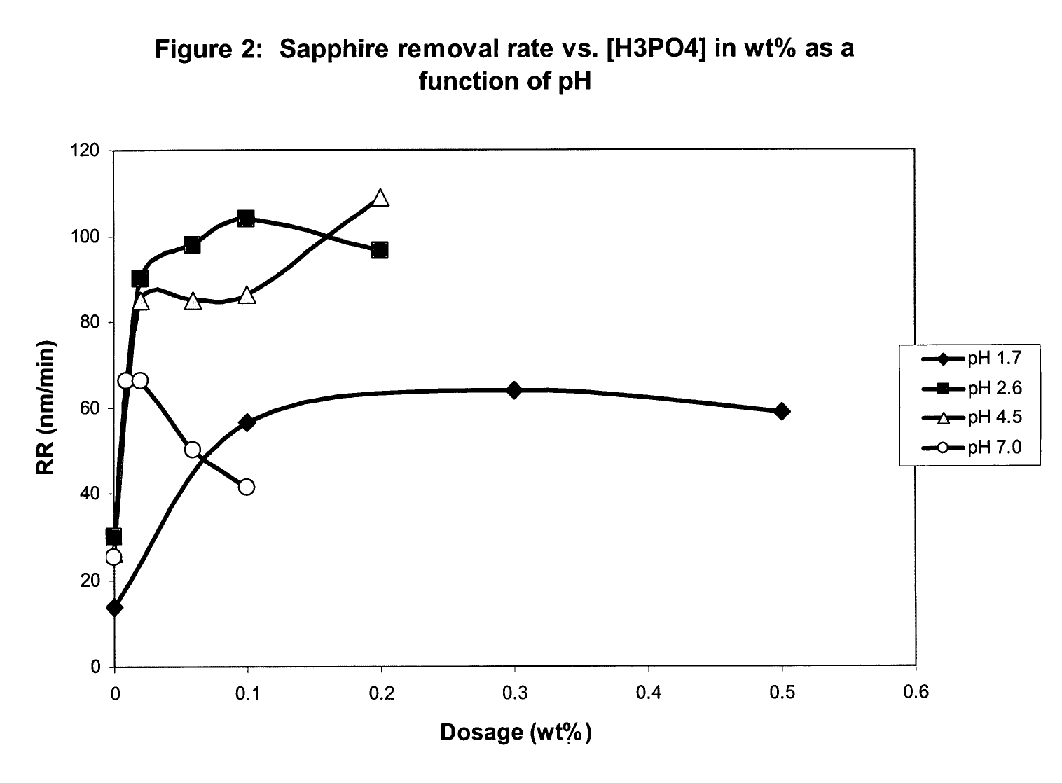

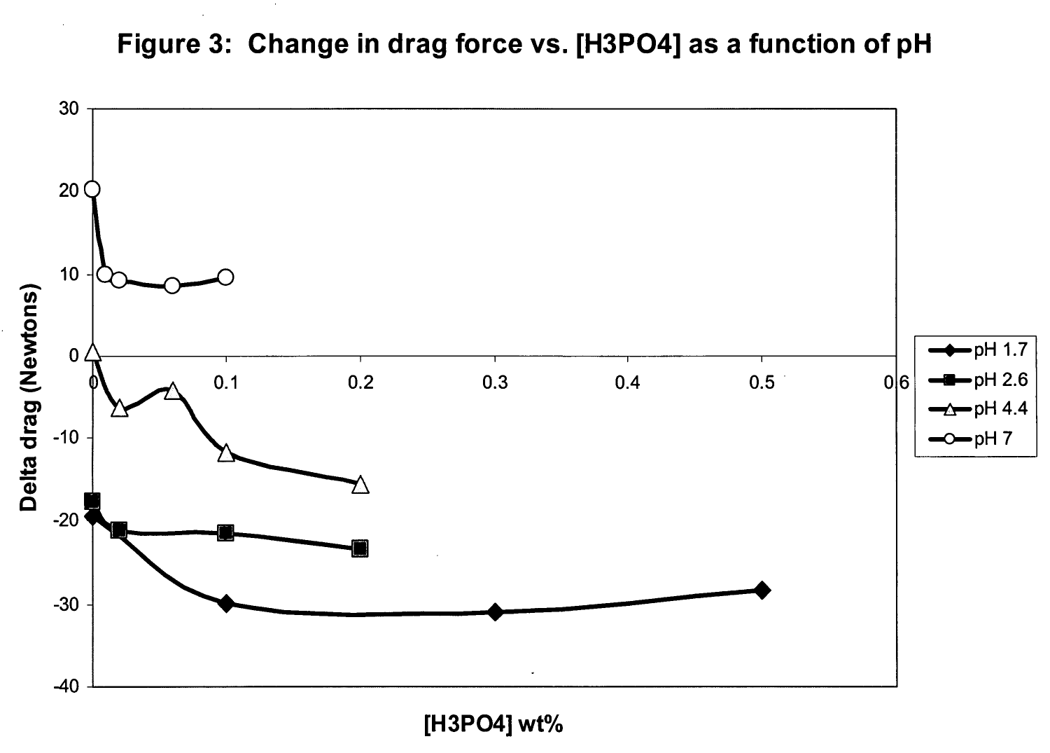

FIG. 2 shows a graph illustrating the sapphire removal rates of the series of slurries described below in Examples 16-34. Each line of the graph of FIG. 2 represents the sapphire removal rates for a series of slurries having varying concentrations of phosphoric acid. FIG. 3 shows a chart illustrating the change in friction of the series of slurries described below in Examples 16-34. Each line of the graph of FIG. 3 represents the change in friction of a series of slurries having varying concentrations of phosphoric acid.

### Examples 16-19

A series of slurries were prepared as in Example 1, except with varying levels of phosphoric acid, and adjusted to pH 1.7 with 10% HCl or 10% KOH, as needed. The final concentrations of phosphoric acid were 0% (Example 16), 0.1% (Example 17), 0.3% (Example 18), and 0.5% (Example 19). The substrate, polishing tool and polishing conditions were as described for Examples 1-8, above. Examples 16-19 are shown in FIGS. 2-3 as data points represented by the diamond symbols.

### Examples 20-24

A series of slurries were prepared as described in Example 1 with varying levels of phosphoric acid, and adjusted to pH 2.6 with 10% HCl or 10% KOH, as needed. The final concentrations of phosphoric acid were 0% (Example 20), 0.02% (Example 21), 0.06% (Example 22), 0.1% (Example 23), and 0.2% (Example 24). The substrate, polishing tool and polishing conditions were as described for Examples 1-8, above. Examples 20-24 are shown in FIGS. 2-3 as the data points represented by the square symbols.

### Examples 24-28

A series of slurries were prepared as described in Example 1 with varying levels of phosphoric acid, and adjusted to pH 4.5 with 10% HCl or 10% KOH, as needed. The final concentrations of phosphoric acid were 0% (Example 24), 0.02% (Example 25), 0.06% (Example 26), 0.1% (Example 27), and 0.2% (Example 28). The substrate, polishing tool and polishing conditions were as described for Examples 1-8, above. Examples 24-28 are shown in FIGS. 2-3 as the data points represented by the triangle symbols.

### Examples 29-33

A series of slurries were prepared as described in Example 1 with varying levels of phosphoric acid, but adjusted to pH 7.0 with 10% HCl or 10% KOH, as needed. The final concentrations of phosphoric acid were 0% (Example 29), 0.01% (Example 30), 0.02% (Example 31), and 0.1% (Example 32). The substrate, polishing tool and polishing conditions were as described for Examples 1-8, above. Examples 29-33 are shown in FIGS. 2-3 as the data points represented by the circle symbols.

FIG. 2 illustrates the effect of phosphoric acid on sapphire removal rates at varying concentrations of phosphoric acid and pH. As illustrated, sapphire removal rates are pH dependent, with sapphire removal rates decreasing at low pH and high pH. Sapphire removal rates were greatest at pH 2.6 and 4.5.

One drawback with the use of abrasive particles is the generation of heat caused by friction when abrasive particles polish the substrates. Use of increased concentrations of abrasive particles contributes to the frictional heat generated, thereby contributing to degradation of polishing pads, for example.

FIG. 3 illustrates the change in drag force in Newtons of Examples 16-33, as described above. The change in drag force is a measure of the friction level of the slurries. As with FIG. 2, the data points represented by the diamond symbols correspond to Examples 16-19, as described above. Moreover, the data points represented by the square symbols correspond to Examples 20-24, as described above. The data points represented by the triangle symbols correspond to Examples 24-28, as described above; and the data points represented by the circle symbols correspond to Examples 29-33, as described above. As illustrated, the change in drag force increased when pH levels increased. The change in drag force levels (and hence, the friction levels) were lowest at pH 1.7 and 2.6.

While this invention has been described with an emphasis upon preferred embodiments, it will be obvious to those of ordinary skill in the art that variations of the preferred embodiments may be used and that it is intended that the invention may be practiced otherwise than as specifically described herein. Accordingly, this invention includes all modifications encompassed within the spirit and scope of the invention as defined by the following claims.

1. A method for polishing a substrate comprising the steps of:
providing a composition comprising an abrasive, a liquid carrier, and a phosphorus-type mono-acid wherein said composition has a pH of between about 1 and about 7;
providing a substrate selected from the group consisting of sapphire and aluminum oxynitride;
providing means for physically abrading the substrate; and
abrading at least a portion of the substrate by contacting the substrate with the means for physically abrading the substrate and the composition.

2. (canceled)

3. The method of claim 1 wherein the sapphire is single crystal sapphire.

4. The method of claim 1 wherein the means for physically abrading the substrate is a polishing pad.

5. (canceled)

6. The method of claim 1 wherein the phosphorus-type mono-acid is selected from the group consisting of phosphoric acid, phosphonoacetic acid, phosphorous acid, methyl phosphonic acid, and mixtures thereof.

7. The method of claim 1 wherein the phosphorus-type mono-acid is phosphoric acid.

8. The method of claim 1 wherein the composition has a pH of between about 2 and about 4.5.

9. The method of claim 1 wherein the abrasive comprises silica.

10. The method of claim 1 wherein the acid concentration is greater than about 0.0025 percent by weight.

11. The method of claim 1 wherein the acid concentration is greater than about 0.01 percent by weight.

12. A sapphire wafer polished by the method of claim 1.

13. The sapphire wafer of claim 12 wherein the average surface roughness is less than about 1.0 nm in a 2×2 μm scan area.

14. The method of claim 7 wherein the concentration of phosphoric acid is greater than about 0.0025 percent by weight.

15. The method of claim 7 wherein the concentration of phosphoric acid is greater than 0.01 percent by weight.

16. The method of claim 7 wherein the concentration of phosphoric acid is about 0.03 percent by weight.

17. The method of claim 14 wherein the pH is between about 2 and about 4.5.

18. A chemical mechanical polishing system comprising:
a composition comprising an abrasive, a liquid carrier, and a phosphorus-type mono-acid wherein said composition has a pH of between about 1 and about 7;
a substrate selected from the group consisting of sapphire and aluminum oxynitride; and
means for physically abrading the substrate.

19. (canceled)

20. The chemical mechanical polishing system of claim 18 wherein the substrate is single crystal sapphire.

21. The chemical mechanical polishing system of claim 18 wherein the means for physically abrading the substrate is a polishing pad.

22. The chemical mechanical polishing system of claim 21 wherein the polishing pad is a grooved polyurethane pad.

23. The chemical mechanical polishing system of claim 18 wherein the phosphorus-type mono-acid is selected from the group consisting of phosphoric acid, phosphonoacetic acid, phosphorous acid, methyl phosphonic acid, and mixtures thereof.

24. The chemical mechanical polishing system of claim 18 wherein the phosphorus-type mono-acid is phosphoric acid.

25. The chemical mechanical polishing system of claim 18 wherein the composition has a pH of between about 2 and about 4.5.

26. The chemical mechanical polishing system of claim 18 wherein the abrasive is silica.

27. The chemical mechanical polishing system of claim 18 wherein the acid concentration is greater than about 0.0025 percent by weight.

28. The chemical mechanical polishing system of claim 18 wherein the acid concentration is greater than about 0.01 percent by weight.

29. The chemical mechanical polishing system of claim 24 wherein the concentration of phosphoric acid is greater than about 0.0025 percent by weight.

30. The chemical mechanical polishing system of claim 24 wherein the concentration of phosphoric acid is greater than about 0.01 percent by weight.

31. The chemical mechanical polishing system of claim 24 wherein the concentration of phosphoric acid is about 0.03 percent by weight.

32. The chemical mechanical polishing system of claim 29 wherein the pH is between about 2 and about 4.5.
